(19) United States
(12) Patent Application Publication
(10) Pub. No.: US 2026/0367178 A1
(43) Pub. Date: Nov. 19, 2026

(54) METHOD AND APPARATUS FOR DIAGNOSING A CELL ABNORMALITY

(71) Applicants: HYUNDAI MOTOR COMPANY, Seoul (KR); KIA CORPORATION, Seoul (KR)

(72) Inventor: Ji Il Kim, Hwaseong-si (KR)

(73) Assignees: HYUNDAI MOTOR COMPANY, Seoul (KR); KIA CORPORATION, Seoul (KR)

(21) Appl. No.: 19/391,429

(22) Filed: Nov. 17, 2025

(30) Foreign Application Priority Data
May 13, 2025 (KR) 10-2025-0061604

(51) Int. Cl. G01R 31/396; B60L 3/00; G01R 31/3835; H01M 10/42

(52) U.S. Cl. CPC G01R 31/396; B60L 3/0046; G01R 31/3835; H01M 10/4285; B60L 2240/547; H01M 2220/20

(57) ABSTRACT

A method and an apparatus for diagnosing a cell abnormality, which set a reference value for a voltage deviation by factoring in vehicle operating information such as a driving distance and a state of charge, and enable reliable diagnosis of battery cell conditions based on the set reference value, are disclosed. The method includes: receiving, by a processor, data including voltage information for a plurality of cells of an electric vehicle, driving distance information of the electric vehicle, and state-of-charge information of the electric vehicle; setting, by the processor, a reference voltage deviation by factoring a correction value based on the state-of-charge information into a voltage deviation trend line determined based on the received voltage information and driving distance information; determining, by the processor, a cell in which a voltage deviation exceeding the reference voltage deviation has repeatedly occurred; and determining, by the processor, the cell as a diagnostic target.

### CROSS-REFERENCE TO RELATED APPLICATION

This application claims under 35 U.S.C. § 119(a) the benefit of and the priority to Korean Patent Application No. 10-2025-0061604 filed on May 13, 2025, the entire contents of which are incorporated herein by reference.

### TECHNICAL FIELD

The present disclosure relates to a method and an apparatus for diagnosing a cell abnormality. Particularly, the method and the apparatus analyze a cell voltage deviation based on operating information of a vehicle and determine a cell exhibiting a sign of an abnormality.

### BACKGROUND

An electric vehicle battery comprises a plurality of cells, and a cell-to-cell voltage deviation is utilized as an important indicator for diagnosing a state of the battery. In general, if the voltage of a particular cell is consistently higher or lower than the voltage of another cell, the cell may be considered to have performance degradation or a potential fault. Accordingly, various fault diagnosis technologies using cell-to-cell voltage deviations have been studied, and some voltage deviation-based diagnostic logic based on a certain threshold has been applied to electric vehicle systems.

A conventional voltage deviation diagnostic method involves uniformly applying a certain threshold (e.g., 100 mV) or taking into account solely the highest voltage deviation at individual points in time (i.e., time points) to diagnose cell abnormality. However, such a conventional diagnostic method has several limitations.

For example, a voltage deviation may naturally vary depending on a state of charge (SOC), a driving distance, or current conditions. However, the conventional diagnostic method does not take these factors into account but makes a determination solely based on a fixed threshold. Accordingly, false detection may occur.

In addition, a pattern in which a voltage deviation temporarily increases and then recovers (e.g., a bumpy pattern), or a single spike caused by an unstable voltage fluctuation at a low state of charge should be interpreted as a deviation within a normal range rather than as a cell fault. However, the conventional diagnostic method has difficulty distinguishing between the cases, resulting in an unnecessary maintenance request and an associated warning. Similarly, if an abnormal deviation repeatedly occurs in the same cell or if an abnormal deviation persists over a certain period of time, there is a high likelihood of an actual fault. However, a conventional diagnostic method based on a single-point-in-time has difficulty in identifying such trends.

Accordingly, there is a need for diagnostic logic capable of clearly distinguishing between signals of normal voltage deviation and abnormal voltage deviation caused by vehicle operating conditions, and identifying a long-term trend in the state of a cell. The subject matter described in this background section is intended to promote an understanding of the background of the disclosure and thus may include subject matter that is not already known to those of ordinary skill in the art. The statements in this section merely provide background information related to the present disclosure and may not constitute prior art.

### SUMMARY

Various aspects of the present disclosure provide a method and an apparatus for diagnosing a cell abnormality, which set a reference value for a voltage deviation by factoring in vehicle operating information such as a driving distance and a state of charge, and enable reliable battery cell state diagnosis based on the set reference value.

A method for diagnosing a cell abnormality according to an embodiment of the present disclosure includes receiving, by a processor, data including voltage information for a plurality of cells of an electric vehicle, driving distance information of the electric vehicle, and state-of-charge information of the electric vehicle. The method further includes setting, by the processor, a reference voltage deviation by factoring a correction value based on the state-of-charge information into a voltage deviation trend line determined based on the received voltage information and driving distance information. The method further includes determining, by the processor, a cell in which a voltage deviation exceeding the reference voltage deviation has repeatedly occurred. The method further includes determining, by the processor, the identified cell as a diagnostic target.

According to an embodiment of the present disclosure, the data that satisfies preset data collection conditions is exclusively received. The preset data collection conditions include numerical conditions for at least one of a time condition for a time point at which the data is collected, the driving distance information, or the state-of-charge information.

According to an embodiment of the present disclosure, the reference voltage deviation is set by referring to a statistical reference value predefined based on a vehicle type of the electric vehicle, and based on a result of comparing the statistical reference value with a preset threshold.

According to an embodiment of the present disclosure, based on the predefined statistical reference value exceeding the preset threshold, the reference voltage deviation is set based on a highest voltage deviation of the electric vehicle.

According to an embodiment of the present disclosure, based on the predefined statistical reference value being equal to or lower than the preset threshold, the reference voltage deviation is set based on the preset threshold.

According to an embodiment of the present disclosure, the method further includes determining the predefined statistical reference value based on voltage deviation data collected in advance from a plurality of electric vehicles, or referring to the predetermined statistical reference value.

According to an embodiment of the present disclosure, the voltage deviation trend line is determined through linear regression analysis based on the driving distance information.

According to an embodiment of the present disclosure, the correction value is an offset value determined based on a difference between an average voltage deviation value determined for each segment of the state-of-charge information and an average value of a segment having a lowest average voltage deviation value among the segments.

According to an embodiment of the present disclosure, based on a voltage deviation repeatedly exceeding the reference voltage deviation occurring in the cell for a predetermined number of times or more than the predetermined number of times, the cell is determined as a diagnostic target.

According to an embodiment of the present disclosure, identification information of the cell is stored at each time point at which the reference voltage deviation is exceeded to determine whether an abnormality repeatedly occurs in the cell.

According to an embodiment of the present disclosure, based on the voltage deviation of the identified cell decreasing as a driving distance increases, the cell is excluded from a diagnosis.

According to an embodiment of the present disclosure, a slope of a trend line for the voltage deviation of the cell is analyzed. Based on the slope being less than or equal to a threshold slope, the voltage deviation of the cell is determined to be decreasing.

An apparatus for diagnosing a cell abnormality according to an embodiment of the present disclosure includes a memory configured to store at least one instruction. The apparatus further includes a processor configured, by executing the at least one instruction, to receive data including voltage information for a plurality of cells of an electric vehicle, driving distance information of the electric vehicle, and state-of-charge information of the electric vehicle. The processor is further configured to set a reference voltage deviation based on a statistical reference value predefined based on a vehicle type of the electric vehicle and the received data. The processor is further configured to determine a cell in which a voltage deviation exceeding the reference voltage deviation has repeatedly occurred. The processor is further configured to determine the cell as a diagnostic target.

According to an embodiment of the present disclosure, the processor is further configured to exclusively receive voltage information for a plurality of cells, driving distance information, and state-of-charge information that satisfy preset collection conditions. The preset collection conditions include numerical conditions for at least one of a time condition for a time point at which the data is collected, the driving distance information, or the state-of-charge information.

According to an embodiment of the present disclosure, the processor is further configured to set the reference voltage deviation by determining a voltage deviation trend line based on the voltage information and the driving distance information and factoring a correction value based on the state-of-charge information into the determined voltage deviation trend line.

According to an embodiment of the present disclosure, the voltage deviation trend line is determined through linear regression analysis based on the driving distance information. The correction value is an offset value determined based on a difference from a lowest average voltage deviation value among average voltage deviation values determined for each segment of the state-of-charge information.

According to an embodiment of the present disclosure, based on a voltage deviation repeatedly exceeding the reference voltage deviation occurring in the cell for a predetermined number of times or more than the predetermined number of times, the processor is further configured to determine the cell as a diagnostic target and store identification information of the cell.

According to an embodiment of the present disclosure, the processor is further configured to analyze a slope of a trend line for the voltage deviation of the cell based on the driving distance. The processor is further configure to exclude the cell from a diagnosis based on the slope being less than or equal to a threshold slope.

According to an aspect of the present disclosure, voltage deviations of the respective cells may be selected as diagnosable data, based on a variety of operating information including voltage information for a plurality of cells of a vehicle, driving distance information, and state-of-charge information of the vehicle. The data may then be statistically analyzed to diagnose whether an abnormality is present in any of the cells.

In particular, in the present disclosure, instead of setting the reference value for a cell voltage deviation as a single fixed threshold, a reference voltage deviation optimized for the operating conditions of each vehicle may be dynamically determined by also factoring in the vehicle's statistical values by vehicle type, trend lines based on an increase in driving distance, and correction values based on the state of charge. Accordingly, it is possible to effectively resolve the issue of false detection caused by changes in the operating environment, such as state of charge, driving distance, and ambient temperature, which occurs in conventional diagnostic logic.

In addition, the present disclosure may not determine the presence of an abnormality solely based on whether the deviation exceeds the reference value at a single time point, but may also consider whether the deviation repeatedly exceeds the reference value in the same cell and whether the deviation tends to persist or decrease as time or a driving distance increases. Accordingly, in the present disclosure, for a cell in which an abnormality repeatedly occurs, if the voltage deviation gradually decreases, the voltage deviation may be considered to be within a normal range of natural recovery, and the cell may be excluded from the diagnosis. In contrast, a cell in which the abnormal deviation persists or increases may be determined to have an ongoing fault and finally confirmed as a diagnostic target.

Through such a multi-stage evaluation structure, the present disclosure may improve the precision and reliability of diagnosis beyond simply detecting an abnormality. The present disclosure may significantly enhance battery life prediction and vehicle maintenance efficiency by preventing the occurrence of an unnecessary warning or premature maintenance. Furthermore, since the diagnostic logic criteria are derived on a statistical basis, the method and the apparatus for diagnosing a cell abnormality, which may be applied to a new vehicle and continuously improve diagnostic performance through periodic updates of the reference value, may be implemented.

The effects which may be achieved in the present disclosure are not limited to the effects mentioned above, and other technical effects not mentioned above should be clearly appreciated by those having ordinary skill in the art from the present disclosure.

### BRIEF DESCRIPTION OF THE DRAWINGS

FIG. 1 is a block diagram illustrating an apparatus for diagnosing a cell abnormality according to an embodiment of the present disclosure.

FIG. 2 is a view illustrating the apparatus for diagnosing a cell abnormality according to an embodiment of the present disclosure.

FIG. 3 is a flowchart illustrating a method for diagnosing a cell abnormality according to an embodiment of the present disclosure.

FIG. 4 is a graph showing the distribution of voltage deviations based on a state of charge according to an embodiment of the present disclosure.

FIG. 5 is an example table of correction values determined for each state of charge segment according to an embodiment of the present disclosure.

FIG. 6 is a view illustrating the method for diagnosing a cell abnormality according to an embodiment of the present disclosure.

### DETAILED DESCRIPTION

Various embodiments of the present disclosure are described in detail below with reference to the accompanying drawings. Prior to the detailed description, it should be noted that the terms and words used in the present disclosure should not be interpreted as being limited to their ordinary or dictionary meanings. Rather, they should be interpreted according to the meanings and concepts consistent with the technical spirit of the present disclosure, based on the principle that an inventor may appropriately define the concept of a term to best describe the disclosure of the inventor. Accordingly, it should be understood that the embodiments described herein and the configurations illustrated in the drawings are merely some of the various embodiments of the present disclosure and do not represent the entirety of the technical spirit of the present disclosure. Accordingly, there may be various equivalents and modifications that may replace them as of the time of filing. In addition, as used herein, the terms “comprise and include” and/or “comprising and including” are intended to specify the presence of the mentioned shapes, numbers, steps, operations, members, components, and/or groups thereof. The terms “comprise and include” and/or “comprising and including” are not intended to exclude the presence or addition of at least one of other shapes, numbers, operations, members, components, and/or groups thereof. In addition, when describing embodiments of the present disclosure, the terms such as “may” and “may be” may include “at least one of the embodiments of the present disclosure.”

In addition, to facilitate better understanding of the present disclosure, the accompanying drawings may not be to scale, and the dimensions of some components may be exaggerated. In addition, the same reference numerals may be used for the same or equivalent components in different embodiments.

A statement that two objects of comparison are “identical” means that they are “substantially identical.” Accordingly, “substantially identical” may include, for example, a deviation within 5%, which is considered negligible in the art. In addition, uniformity of a parameter in a given region may mean uniformity from an average perspective.

Throughout the present disclosure, each component may be singular or plural, unless particularly stated otherwise.

When any component is disposed on “the upper (or lower) portion” of a component, or “above (or below)” a component, this may mean not only that any component is disposed in contact with the upper surface (or lower surface) of the component, but also that another component may be interposed between any components disposed above (or below) the components.

In addition, when a component is described as being “connected,” “coupled,” or “joined” to another component, it should be understood that the components may be directly connected or joined to each other, or may be “connected,” “coupled,” or “joined” to another component “interposed” between each of the components, or through another component. In addition, when a part is described as being electrically coupled to another part, this includes not only a direct electrical connection but also an indirect connection with another element interposed between them.

Throughout the present disclosure, when “A and/or B” is stated, it means A, B, or A and B, unless particularly stated otherwise. In other words, “and/or” includes all combinations or any combination of a plurality of items listed. When “C to D” is stated, it means a range from C to D, unless particularly stated otherwise. When a controller, module, unit, component, device, element, or the like of the present disclosure is described as having a purpose or performing an operation, function, or the like, the controller, module, unit, component, device, element, or the like should be considered herein as being “configured to” meet that purpose or to perform that operation or function. Each controller, module, unit, component, device, element, and the like may separately embody or be included with a processor and a memory, such as a non-transitory computer readable media, as part of the apparatus.

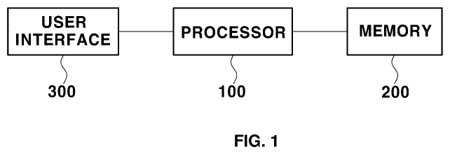

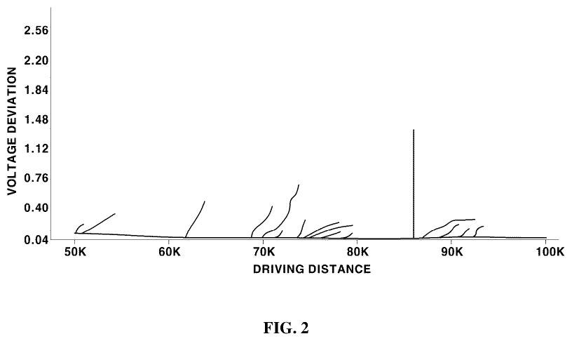

FIG. 1 is a block diagram illustrating an apparatus for diagnosing a cell abnormality according to an embodiment of the present disclosure. FIG. 2 is a view illustrating the apparatus for diagnosing a cell abnormality according to an embodiment of the present disclosure.

Referring to FIG. 1, the apparatus for diagnosing a cell abnormality according to an embodiment of the present disclosure may include a processor 100, a memory 200, and a user interface 300. The processor 100 may be an entity that diagnoses an abnormality in a plurality of cells in an electric vehicle based on received data. In particular, the processor 100 according to the present disclosure may analyze a change in voltage deviations of each cell based on a driving distance and may detect a cell exhibiting an abnormality.

The term “electric vehicle” as used herein is used for convenience of description and may be interpreted as including all vehicles or means of transportation that include a battery system including a plurality of cells. Accordingly, the present disclosure is equally applicable not only to an electric vehicle but also to a hybrid vehicle, a plug-in hybrid vehicle, and other electric power-based vehicles.

Referring to FIG. 2, each point may represent a cell voltage deviation at a particular point in time (i.e., time point), and the graph may represent how cell voltage deviations (y-axis) are distributed in response to an increase in the driving distance (x-axis). As shown in FIG. 2, most cells are distributed within a stable range defined by a certain reference threshold. However, in some cells, a voltage deviation that spikes sharply (outlier) may be observed in a certain driving distance segment. Such a spike may be a transient phenomenon caused by a single disturbance or, in fact, may be a structural abnormality that occurs repeatedly in the same cell. Accordingly, the processor 100 may analyze a trend of changes in cell voltage deviations along the driving distance axis. Based on the analyzed trend, the processor 100 may function as an entity that more reliably identifies an abnormal cell by determining whether a particular cell repeatedly exceeds or continuously exceeds a baseline for a long period of time.

Various embodiments described herein may be implemented as software including at least one instruction stored in a storage medium (e.g., an internal memory or external memory) readable by a machine (e.g., a computing device or the processor 100). For example, the machine or the processor 100 may retrieve the at least one instruction stored in the storage medium and may execute the retrieved instructions. The at least one instruction may include code generated by a compiler or code executable by an interpreter. The storage medium readable by the machine or the processor 100 may be provided in the form of a non-transitory storage medium. Here, “non-transitory” merely means that the storage medium is a tangible device and does not contain signals (e.g., electromagnetic waves), and the term does not distinguish between a case where data is stored semi-permanently in the storage medium and a case where data is stored temporarily the storage medium.

The processor 100 may include hardware (e.g., a controller) for implementing various embodiments described herein. The processor 100 may include at least one core and may include a processor of a computing device for data analysis and deep learning, such as a central processing unit (CPU), a general-purpose graphics processing unit (GPGPU), a tensor processing unit (TPU), an application processor (AP), an application-specific integrated circuit (ASIC), and a field programmable gate array (FPGA). A processor for deep learning may be controlled to process input data, based on a predefined operation rules or an artificial intelligence model stored in memory. If at least one processor are a dedicated AI processor, the dedicated AI processor may be designed with a hardware architecture that is specialized for processing a particular AI model.

The memory 200 may store a variety of information and maps required to implement various embodiments described herein. The memory 200 may include at least one of the following types of storage media: flash memory type, hard disk type, multimedia card micro type, card-type memory (e.g., SD or XD memory), random access memory (RAM), static random access memory (SRAM), dynamic random-access memory (DRAM), magnetic random-access memory (MRAM), read-only memory (ROM), electrically erasable programmable read-only memory (EEPROM), programmable read-only memory (PROM), magnetic memory, magnetic disk, or optical disk. In addition, the memory 200 may include any type of computer-readable recording medium well known in the art associated with the present disclosure. In addition, examples of storage or recording media may include media managed by an application store that distributes applications, or by a site, server, or the like that provides or distributes a variety of other software. The foregoing description of memory is merely illustrative, and the present disclosure is not limited thereto.

The user interface 300 may be configured to output a diagnostic result under control of the processor 100 or to receive input of a setting value for diagnostic conditions from a user. The user interface 300 may include, for example, a display device, a touchscreen, or a button-based input means and may provide the user with a variety of information, such as identification information of a diagnosed abnormal cell, the number of occurrences of the abnormality, a trend analysis result, and a warning notification. In addition, the user may transmit, through the user interface 300, a request message for a detailed analysis result for a particular cell or may adjust settings, such as diagnostic criteria, a statistical reference value, or a threshold.

The apparatus for diagnosing a cell abnormality according to the present disclosure may be implemented in a configuration that includes the processor 100 configured to set a reference voltage deviation based on cell voltage information, driving distance information, and state-of-charge information and to diagnose an abnormal cell that repeatedly exceeds the reference voltage deviation. A more detailed configuration of the apparatus is described in detail below with reference to embodiments of the method of the present disclosure, which is described below.

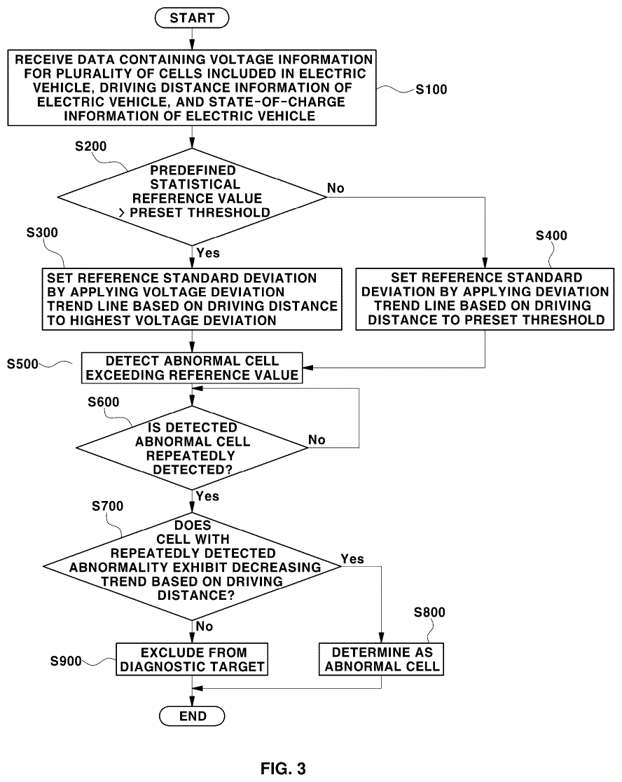

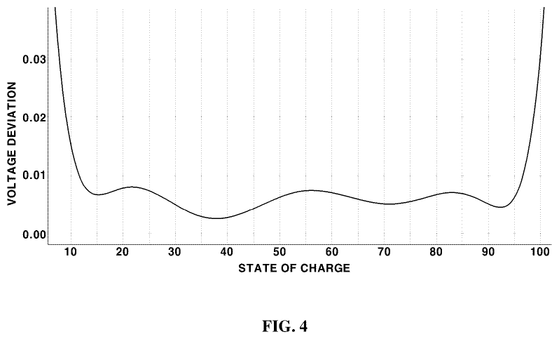

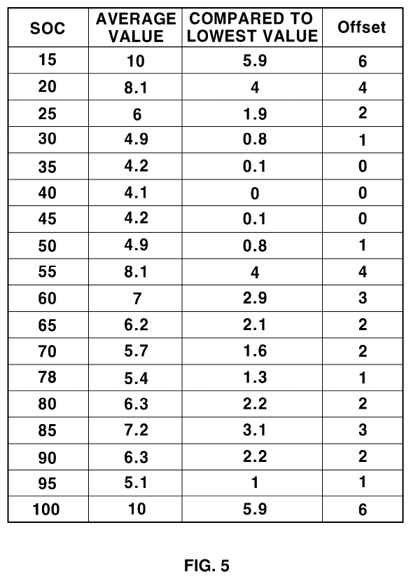

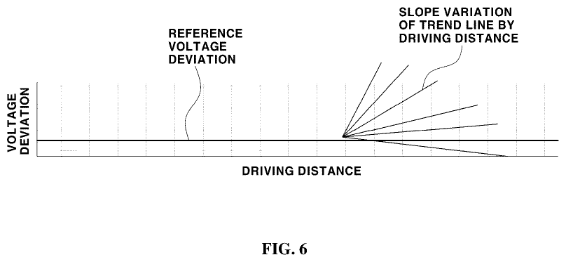

FIG. 3 is a flowchart illustrating a method for diagnosing a cell abnormality according to an embodiment of the present disclosure. FIG. 4 is a graph showing the distribution of voltage deviations based on a state of charge according to an embodiment of the present disclosure. FIG. 5 is an example table of correction values determined for each state of charge segment according to an embodiment of the present disclosure. FIG. 6 is a view illustrating the method for diagnosing a cell abnormality according to an embodiment of the present disclosure.

Referring to FIG. 3, the processor 100 may receive data containing voltage information for a plurality of cells included in the electric vehicle, driving distance information of the electric vehicle, and state-of-charge information of the electric vehicle.

To ensure the accuracy and reliability of the data, the processor 100 may receive exclusively data that satisfies preset data collection conditions and may utilize the received data for diagnosing a cell abnormality. For example, the processor 100 may consider data, which is collected after a certain period of time has elapsed since a vehicle ignition is turned on, as valid, and the processor 100 may receive the data exclusively. Immediately after the ignition is turned on, the vehicle's battery system, sensor, or the like may have not completed electrical stabilization. Accordingly, measured voltage information may contain a momentary spike or noise. In addition, the cell voltage information immediately after the ignition is turned on may momentarily fluctuate due to external load and internal resistance and may not correspond to an open circuit voltage (OCV). Accordingly, the cell voltage information may not accurately reflect the actual characteristics of the cell. Accordingly, the processor 100 may ensure the accuracy and reliability of data utilized for diagnosis by receiving data after the cell voltage has been electrically stabilized, as a time condition for the time at which the data is collected.

In addition, the processor 100 may receive exclusively data that satisfies numerical conditions for at least one of driving distance information or state-of-charge information of the electric vehicle. For example, the processor 100 may receive data corresponding to a case where a cumulative driving distance (odometer) of the electric vehicle exceeds a certain reference value (e.g., 1,000 km). Because an abnormality associated with a voltage deviation tends to occur primarily in a vehicle that has driven a certain distance or more, the processor 100 may collect data exclusively from a vehicle that exceeds a certain value, so as to enhance the overall efficiency and reliability of the diagnosis.

Similarly, the processor 100 may receive data corresponding to a case where the state of charge is at or above a preset lower limit (e.g., 10%). In a low state of charge segment, the voltage deviation may become abnormally large due to an increase in the internal resistance of the battery or a change in the voltage response characteristics of the battery. Accordingly, the processor 100 may exclusively receive data when the state of charge is at or above a certain level, so as to receive data from which an abrupt voltage change or an influence of noise is excluded. The abrupt voltage change or the influence of noise may occur regardless of the actual cell state,

Furthermore, if a current value at the time of receiving data falls outside a preset threshold range (e.g.,−50 A to +50 A), the processor 100 may not collect the data. Voltage information measured in a state of rapid charge or discharge may be more significantly affected by a disturbance than by the normal voltage characteristics of the cell. Accordingly, the processor 100 may receive exclusively data measured in a segment where current conditions are stable, so as to minimize an influence of voltage fluctuations caused by overcurrent. The processor 100 may ensure the quality and reliability of data, which is the basis of diagnosis, through the aforementioned filtering process of the data (S100).

The processor 100 may refer to a predefined statistical reference value based on the vehicle type of electric vehicle and may compare the statistical reference value with a preset threshold. The statistical reference value may correspond to a predetermined value based on cell voltage deviation data collected from a plurality of vehicles. For example, the statistical reference value may be defined as a value of 3 sigma (3^{δ}) that takes into account the mean and standard deviation (δ) of the voltage deviations, but the value may not be particularly limited. The statistical reference value is a statistical limit that represents a highest allowable deviation of a natural distribution, which may occur under normal vehicle operating conditions, and may be predefined for each vehicle type and stored in the memory 200. In addition, the statistical reference value may correspond to an element that may be stored, in the memory 200, in a pre-classified form, factoring in operating characteristics of a particular vehicle type as well as distribution characteristics of voltage deviations, which may vary depending on the state of charge or driving distance segment.

The preset threshold may be utilized as a discriminant baseline for classifying average abnormal trends, which may appear in each vehicle type. For example, the threshold may be set as an upper limit (e.g., 50 mV) of a cell-to-cell voltage deviation, which may occur under normal vehicle operating conditions. A threshold according to the present disclosure may serve as a reference for determining whether a statistically significant abnormality is present. Accordingly, the processor 100 may determine whether a statistical reference value for a particular vehicle exceeds the threshold. The threshold may indicate that the vehicle corresponds to a vehicle type or battery type that tends to exhibit a large voltage deviation on average (S200).

Based on comparing the statistical reference value and the threshold and determining that the statistical reference value exceeds the threshold (Yes in S200), the processor 100 may determine that the vehicle tends to exhibit a relatively large voltage deviation even under a normal operating condition. In other words, such a result may indicate that a battery system of the vehicle is likely to exhibit frequent voltage deviations due to a structural or environmental factor.

For more accurate diagnosis, the processor 100 may determine a voltage deviation trend line that takes into account changes in voltage deviation based on time or a cumulative driving distance. Based on the determined trend line, the processor 100 may dynamically set a reference voltage deviation. For example, the processor 100 may set the reference voltage deviation as shown in [Expression 1] below.

Highest Voltage Deviation+A×(Driving Distance)+SOC Correction Value [Expression 1]

In [Expression 1], the highest voltage deviation may correspond to the largest value of the cell-to-cell voltage deviations measured at a particular time point for the vehicle and may correspond to a vehicle-specific diagnostic baseline, i.e., a basic input value for setting a reference voltage deviation in the present disclosure. The processor 100 may determine a voltage deviation trend line by factoring a tendency for the voltage deviation to increase or change depending on the driving distance into the highest voltage deviation.

The trend line may be based on a statistical pattern in which the voltage deviation increases linearly as the cumulative operating distance of the vehicle increases, and may be defined by A×(Driving Distance) contained in [Expression 1]. A slope A may correspond to a slope coefficient of a trend line statistically derived either on a per-vehicle type basis or for all vehicles. The slope A may correspond to an indicator of how much the voltage deviation increases (or decreases) on average as the driving distance increases, and the slope A may be expressed in units such as mV/km or μV/km. For example, if the voltage deviation tends to increase by an average of 3 mV over a driving distance of 1,000 km, the slope A might be set to 0.003 mV/km. If the amount of vehicle-specific data is insufficient, a common slope coefficient A may be applied by utilizing cumulative data collected from the same vehicle type.

Referring to FIG. 4, in a segment where the state of charge of the electric vehicle is low (approximately 10% or below) or high (approximately 95% or above), the voltage deviation may tend to increase sharply. Such a tendency is a natural characteristic induced by a decrease in electrochemical reactivity and an increase in internal resistance within the battery and may correspond to a voltage deviation unrelated to a fault of the cell itself. Accordingly, to consider such a tendency of voltage deviation based on the state of charge, the processor 100 may analyze the average voltage deviation and the lowest deviation value for each state of charge segment so as to determine an SOC correction value, which is an offset correction value. As shown in [Expression 1], the SOC correction value may be utilized as an element added based on the state of charge during setting a reference voltage deviation, and the processor 100 may quantitatively remove the influence of the state of charge through the SOC correction value.

Referring to FIG. 5, the processor 100 may determine a comparison value (compared to the lowest value) indicating how much higher the average of voltage deviations measured for each state of charge segment is, compared to the lowest average voltage deviation among the state of charge segments. For example, if the average voltage deviation for a 15% state of charge segment is 10 mV, and the lowest average voltage deviation (a 40% state of charge segment) is 4.1 mV, the comparison value for the 15% segment may be determined to be 5.9 mV. In this case, the processor 100 may determine the comparison value as an correction (offset) value based on a predetermined criterion (e.g., a 5% SOC interval). The determined correction value may be factored into each state of charge segment in the process of setting a reference voltage deviation. In this way, the processor 100 may quantitatively compensate for a voltage deviation increase that may naturally occur depending on the state of charge (S300).

In addition, if the predefined statistical reference value is equal to or lower than a preset threshold (No in S200), the processor 100 may utilize the threshold, which is a more conservative reference value, as a starting point instead of utilizing the highest voltage deviation as a starting point as shown in [Expression 1]. In this case, the processor 100 may set a reference voltage deviation by factoring a voltage deviation trend line based on the driving distance and a correction value based on the state of charge into the threshold. This may be defined as shown in [Expression 2] below.

Threshold+A×(Driving Distance)+SOC Correction value [Expression 2]

Here, the threshold may be set as an upper limit (e.g., 50 mV) of the cell-to-cell voltage deviation that may occur under a normal operating condition, and the threshold may be utilized as a baseline for determining whether a statistically significant abnormality is present. In other words, if the voltage deviation of the vehicle tends to be stable overall, the processor 100 may utilize the threshold as a reference to avoid excessive diagnostic sensitivity and reduce the false positive rate. The driving distance-based trend line (A×driving distance) and SOC correction value contained in [Expression 2] are the same as described in step S300 above, and accordingly, repetitive descriptions have been omitted (S400).

Referring to FIG. 6, the processor 100 may detect a cell that exhibits a voltage deviation exceeding the reference voltage deviation set in step S300 or S400.

As illustrated in FIG. 6, the reference voltage deviation may be visualized as a horizontal line, and the voltage deviation of individual cells may be illustrated in the form of points along the driving distance axis. If a voltage deviation exceeding a threshold line set as the reference voltage deviation is detected among the cell voltage deviation values received at each time point, the processor 100 may determine that the cell exhibiting the voltage deviation is an abnormal cell. To determine the repeatability of the abnormal cell described below, the processor 100 may store, in the memory 200, identification information of the cell that has exceeded the reference (S500).

The processor 100 may determine whether a voltage deviation repeatedly exceeds the reference voltage deviation occurs in the same cell for a predetermined number of times or more than the predetermined number of times. For example, if a history of exceeding the reference voltage deviation in a particular cell accumulates with a certain number of times (e.g., five times) or more than the certain number of times, the processor 100 may determine that an abnormal voltage deviation has repeatedly occurred in the cell. Through this determination, the processor 100 may minimize the possibility of false detection caused by temporary noise or one-time deviations resulting from a change in an external condition. The predetermined number of times may be set differently depending on vehicle manufacturer policy or empirical data (S600).

To determine whether the cell identified in step S600 is in fact a cell in which an abnormality has occurred, the processor 100 may analyze a change in the voltage deviation trend. Specifically, the processor 100 may analyze whether the voltage deviation of the identified cell decreases to a predetermined threshold or lower than the predetermined threshold as the driving distance increases. The processor 100 may collect accumulated voltage deviation data for a particular cell along the driving distance axis (or time axis) and may analyze a trend line representing the tendency of the voltage deviation change, based on the collected data. A statistical analysis technique such as linear regression analysis may be utilized as an analysis method. When the abnormal cell repeatedly detected (Yes in S600), the processor 100 may determine a slope of the trend line to determine whether the voltage deviation of the cell is gradually decreasing as the driving distance increases (S700).

If a slope of the trend line is negative, and the absolute value of the slope exceeds a preset decrease threshold (e.g., −0.001 mV/km), the processor 100 may determine that the voltage deviation of the cell is stabilizing based on the driving distance. For example, as illustrated in FIG. 6, even if the voltage deviation of an individual cell exceeds the baseline (e.g., the gray horizontal line), but then exhibits a pattern of continuously converging to the baseline or below the baseline over a certain driving distance segment (Yes in S700), the processor 100 may consider the state of the cell to be gradually stabilizing and may exclude the cell from the diagnosis. In this case, the processor 100 may determine that the voltage deviation of the cell is caused by a temporary factor (e.g., ambient temperature change or transient load). Accordingly, a temporary pattern such as a bumpy pattern may be excluded from the diagnosis (S800).

On the other hand, if the voltage deviation repeatedly occurs in the same cell, and the slope of the trend line is zero or positive, the processor 100 may determine that the cell is an abnormal cell with an ongoing fault. In other words, if the voltage deviation exhibits a pattern of remaining the same or increasing rather than decreasing (No in S700), the processor 100 may finally confirm the cell as a diagnostic target (S900).

As illustrated in the right-side area of FIG. 6, a plurality of trend lines may be visualized, in which the voltage deviation gradually decreases as the driving distance increases. Through such slope analysis, the processor 100 may perform precise diagnosis for the presence of a cell abnormality, based on the persistence and repeatability.

After determining the presence of a cell abnormality, the processor 100 may store, in the memory 200, information such as identification information of the cell in which an abnormality is detected, the number of repeated occurrences, or the trend analysis result or may visually output the information to the user through the user interface 300. The output information may be recorded in a vehicle maintenance history or may be transmitted to a maintenance manager or an external server for use in remote diagnosis and maintenance schedule setting. Furthermore, in addition to storing the diagnostic result, the processor 100 may also transmit the result to an external cloud server depending on the network configuration or may perform control to enable a follow-up action on the abnormality information in conjunction with a maintenance system or remote diagnostic system.

As described above, according to the present embodiments, voltage deviations of the respective cells may be selected as diagnosable data, based on a variety of operating information including voltage information for a plurality of cells included in a vehicle and driving distance information and state-of-charge information of the vehicle. The data may then be statistically analyzed to diagnose whether an abnormality is present in any of the cells. In particular, in the present disclosure, instead of setting the reference value for a cell voltage deviation as a single fixed threshold, a reference voltage deviation optimized for the operating conditions of each vehicle may be dynamically determined by also factoring in the vehicle's statistical values by vehicle type, trend lines based on an increase in driving distance, and correction values based on the state of charge. Accordingly, it is possible to effectively resolve the issue of false detection caused by changes in the operating environment, such as state of charge, driving distance, and ambient temperature, which occurs in conventional diagnostic logic. In addition, the present disclosure may not determine the presence of an abnormality solely based on whether the deviation exceeds the reference value at a single time point, but may also consider whether the deviation repeatedly exceeds the reference value in the same cell and whether the deviation tends to persist or decrease as time or a driving distance increases. Accordingly, in the present disclosure, for a cell in which an abnormality repeatedly occurs, if the voltage deviation gradually decreases, the voltage deviation may be considered to be within a normal range of natural recovery, and the cell may be excluded from the diagnosis. In contrast, a cell in which the abnormal deviation persists or increases may be determined to have an ongoing fault and finally confirmed as a diagnostic target.

Through such a multi-stage evaluation structure, the present disclosure may improve the precision and reliability of diagnosis beyond simply detecting an abnormality. The present disclosure may significantly enhance battery life prediction and vehicle maintenance efficiency by preventing the occurrence of an unnecessary warning or premature maintenance. Furthermore, because the diagnostic logic criteria are derived on a statistical basis, the method and the apparatus for diagnosing a cell abnormality may be applied to a new vehicle and may continuously improve diagnostic performance through periodic updates of the reference value.

As used herein, the terms such as “reference voltage deviation,” “statistical reference value,” “threshold,” and “correction value” may be mathematically or statistically defined as described in certain embodiments. The method of determination or the applied numerical values may vary depending on embodiments of the present disclosure and are not intended to limit the scope of the present disclosure. In addition, expressions such as “abnormal cell,” “trend line,” “bumpy pattern,” and “voltage deviation exceedance” should be interpreted within the scope of meanings understood by those having ordinary skill in the art, in consideration of the entirety of the technical matters described herein.

The implementations described herein may be accomplished as, for example, a method or a process, an apparatus, a software program, a data stream, or a signal. Even if merely discussed in the context of a single form of implementation (e.g., discussed merely as a method), the implementation of features discussed may also be implemented in other forms (e.g., an apparatus or program). A device may be implemented with appropriate hardware, software, and firmware, etc. A method may be implemented in a device, such as a processor, which generally refers to a processing device including, for example, a computer, microprocessor, integrated circuit, or programmable logic device. Processors also include communication devices such as computers, cell phones, personal digital assistants (PDAs) and other devices that facilitate communication of information between end-users.

Although the present disclosure has been described above with reference to limited embodiments and drawings, the present disclosure is not limited thereto. In addition, it should to be understood that various modifications and variations may be made by those having ordinary skill in the art to which the present disclosure pertains within the technical spirit of the present disclosure and the equivalent scope of the claims described below.

What is claimed is:

1. A method for diagnosing a cell abnormality, the method comprising:
receiving, by a processor, data including voltage information for a plurality of cells of an electric vehicle, driving distance information of the electric vehicle, and state-of-charge information of the electric vehicle;
setting, by the processor, a reference voltage deviation by factoring a correction value based on the state-of-charge information into a voltage deviation trend line determined based on the received voltage information and driving distance information;
determining, by the processor, a cell in which a voltage deviation exceeding the reference voltage deviation has repeatedly occurred; and
determining, by the processor, the cell as a diagnostic target.

2. The method of claim 1,
wherein data that satisfies preset data collection conditions is exclusively received, and
wherein the preset data collection conditions comprise numerical conditions for at least one of a time condition for a time point at which the data is collected, the driving distance information, or the state-of-charge information.

3. The method of claim 1, wherein the reference voltage deviation is set by referring to a statistical reference value predefined based on a vehicle type of the electric vehicle, and based on a result of comparing the statistical reference value with a preset threshold.

4. The method of claim 3, wherein based on the predefined statistical reference value exceeding the preset threshold, the reference voltage deviation is set based on a highest voltage deviation of the electric vehicle.

5. The method of claim 3, wherein based on the predefined statistical reference value being equal to or lower than the preset threshold, the reference voltage deviation is set based on the preset threshold.

6. The method of claim 3, further comprising:
determining the predefined statistical reference value based on voltage deviation data collected in advance from a plurality of electric vehicles, or referring to the predetermined statistical reference value.

7. The method of claim 1, wherein the voltage deviation trend line is determined through linear regression analysis based on the driving distance information.

8. The method of claim 1, wherein the correction value is an offset value determined based on a difference between an average voltage deviation value determined for each segment of the state-of-charge information and an average value of a segment having a lowest average voltage deviation value among the segments.

9. The method of claim 1, wherein based on a voltage deviation repeatedly exceeding the reference voltage deviation occurring in the cell for a predetermined number of times or more than the predetermined number of times, the cell is determined as a diagnostic target.

10. The method of claim 9, wherein identification information of the cell is stored at each time point at which the reference voltage deviation is exceeded to determine whether an abnormality repeatedly occurs in the cell.

11. The method of claim 9, wherein based on the voltage deviation of the cell decreasing as a driving distance increases, the cell is excluded from a diagnosis.

12. The method of claim 11, wherein a slope of a trend line for the voltage deviation of the cell is analyzed, and
wherein based on the slope being less than or equal to a threshold slope, the voltage deviation of the cell is determined to be decreasing.

13. An apparatus for diagnosing a cell abnormality, the apparatus comprising:
a memory configured to store at least one instruction; and
a processor configured, by executing the at least one instruction, to:
receive data including voltage information for a plurality of cells of an electric vehicle, driving distance information of the electric vehicle, and state-of-charge information of the electric vehicle;
set a reference voltage deviation based on a statistical reference value predefined based on a vehicle type of the electric vehicle and the received data;
determine a cell in which a voltage deviation exceeding the reference voltage deviation has repeatedly occurred; and
determine the cell as a diagnostic target.

14. The apparatus of claim 13,
wherein the processor is further configured to exclusively receive voltage information for a plurality of cells, driving distance information, and state-of-charge information that satisfy preset collection conditions, and
wherein the preset collection conditions comprise numerical conditions for at least one of a time condition for a time point at which the data is collected, the driving distance information, or the state-of-charge information.

15. The apparatus of claim 13, wherein the processor is further configured to:
set the reference voltage deviation by determining a voltage deviation trend line based on the voltage information and the driving distance information and factoring a correction value based on the state-of-charge information into the determined voltage deviation trend line.

16. The apparatus of claim 15,
wherein the voltage deviation trend line is determined through linear regression analysis based on the driving distance information, and
wherein the correction value is an offset value determined based on a difference from a lowest average voltage deviation value among average voltage deviation values determined for each segment of the state-of-charge information.

17. The apparatus of claim 13, wherein based on a voltage deviation repeatedly exceeding the reference voltage deviation occurring in the cell for a predetermined number of times or more than the predetermined number of times, the processor is further configured to determine the cell as a diagnostic target and store identification information of the cell.

18. The apparatus of claim 17, wherein the processor is further configured to:
analyze a slope of a trend line for the voltage deviation of the cell based on the driving distance; and
exclude the cell from a diagnosis based on the slope being less than or equal to a threshold slope.
